(19) United States
(12) Patent Application Publication
(10) Pub. No.: US 2022/0407496 A1
(43) Pub. Date: Dec. 22, 2022

(54) ACOUSTIC WAVE DEVICES INCLUDING HIGH DENSITY INTERDIGITATED ELECTRODES

(71) Applicant: SKYWORKS SOLUTIONS, INC., Irvine, CA (US)

(72) Inventors: Michael David Hill, Emmitsburg, MD (US); Benjamin Paul Abbott, Irvine, CA (US); Yosuke Hamaoka, Suita-Shi (JP); Hiroyuki Nakamura, Osaka-Fu (JP); Alan Sangone Chen, Leeburg, FL (US)

(21) Appl. No.: 17/806,365

(22) Filed: Jun. 10, 2022

Related U.S. Application Data
(60) Provisional application No. 63/211,232, filed on Jun. 16, 2021.

(51) Int. Cl. H03H 9/02; H03H 9/25; H03H 9/145; H03H 9/64

(52) U.S. Cl. CPC H03H 9/02228; H03H 9/25; H03H 9/14541; H03H 9/6483

(57) ABSTRACT

A acoustic wave resonator comprises a piezoelectric substrate and a plurality of interdigital transducer (IDT) electrodes disposed on the piezoelectric substrate, the plurality of IDT electrodes formed of a mixture of tungsten and chromium to provide for reduction in size and increase in quality factor of the acoustic wave resonator.

### CROSS-REFERENCE TO RELATED APPLICATIONS

This application claims priority under 35 U.S.C. § 119(e) to U.S. Provisional Patent Application Ser. No. 63/211,232 titled “ACOUSTIC WAVE DEVICES INCLUDING HIGH DENSITY INTERDIGITATED ELECTRODES,” filed Jun. 16, 2021, the entire contents of which being incorporated herein by reference for all purposes.

### BACKGROUND

### Technical Field

Embodiments of this disclosure relate to acoustic wave devices, structures and methods for reducing the sizes of same, and the suppression of spurious signals in same.

### Description of Related Technology

Acoustic wave devices, for example, surface acoustic wave (SAW) and bulk acoustic wave (BAW) devices may be utilized as components of filters in radio frequency electronic systems. For instance, filters in a radio frequency front-end of a mobile phone can include acoustic wave filters. Two acoustic wave filters can be arranged as a duplexer.

### SUMMARY

In accordance with one aspect, there is provided an acoustic wave resonator. The acoustic wave resonator comprises a piezoelectric substrate, and a plurality of interdigital transducer (IDT) electrodes disposed on the piezoelectric substrate, the plurality of IDT electrodes formed of a mixture of tungsten and chromium to provide for reduction in size and increase in quality factor of the acoustic wave resonator.

In some embodiments, the resonator further comprises reflector electrodes formed of the mixture of tungsten and chromium.

In some embodiments, the mixture is a two-phase mixture of two different alloys of tungsten and chromium.

In some embodiments, the mixture includes between 5 at % and 95 at % tungsten and from 5 at % to 95 at % chromium.

In some embodiments, the mixture includes about 90 at % tungsten and about 10 at % chromium.

In some embodiments, the resonator is configured as a surface acoustic wave resonator.

In some embodiments, the resonator is configured as a Lamb wave resonator.

In some embodiments, the resonator is included in a radio frequency filter. The radio frequency filter may be included in an electronics module. The electronics module may be included in an electronic device.

### BRIEF DESCRIPTION OF THE DRAWINGS

Embodiments of this disclosure will now be described, by way of non-limiting example, with reference to the accompanying drawings.

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of a surface acoustic wave resonator;

FIG. 3 is a cross-sectional view of a portion of a Lamb mode acoustic wave resonator;

FIG. 4 is a phase diagram of the tungsten-chromium system;

FIG. 5 is a schematic diagram of a radio frequency ladder filter;

FIG. 6 is a block diagram of one example of a filter module that can include one or more acoustic wave elements according to aspects of the present disclosure;

FIG. 7 is a block diagram of one example of a front-end module that can include one or more filter modules according to aspects of the present disclosure; and

FIG. 8 is a block diagram of one example of a wireless device including the front-end module of FIG. 7.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

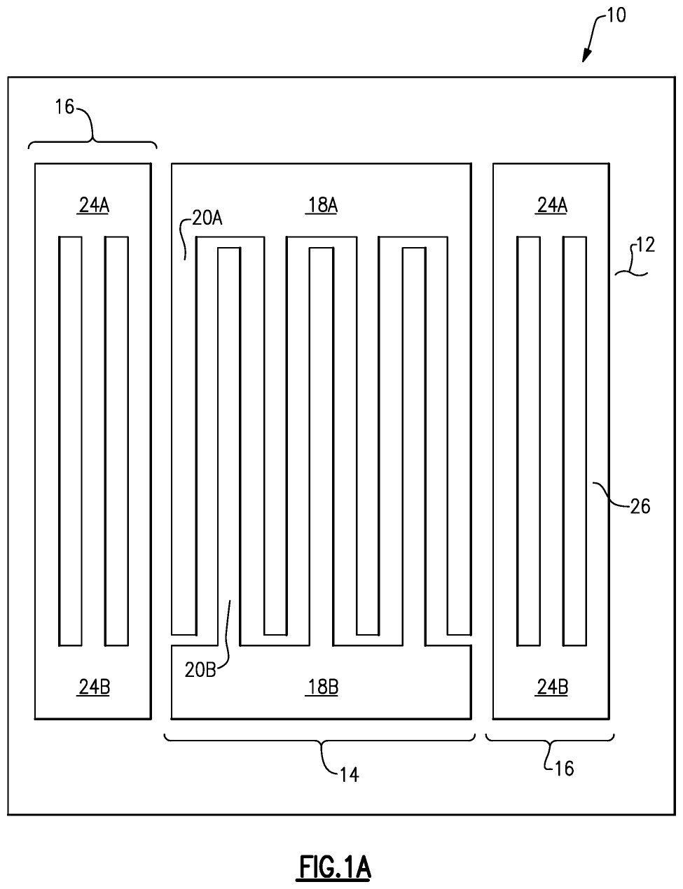

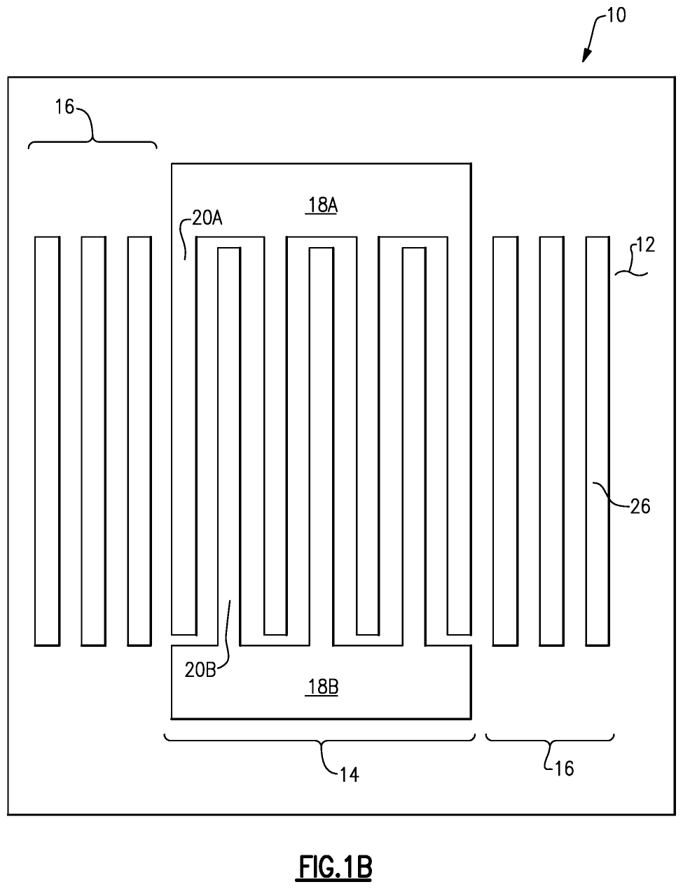

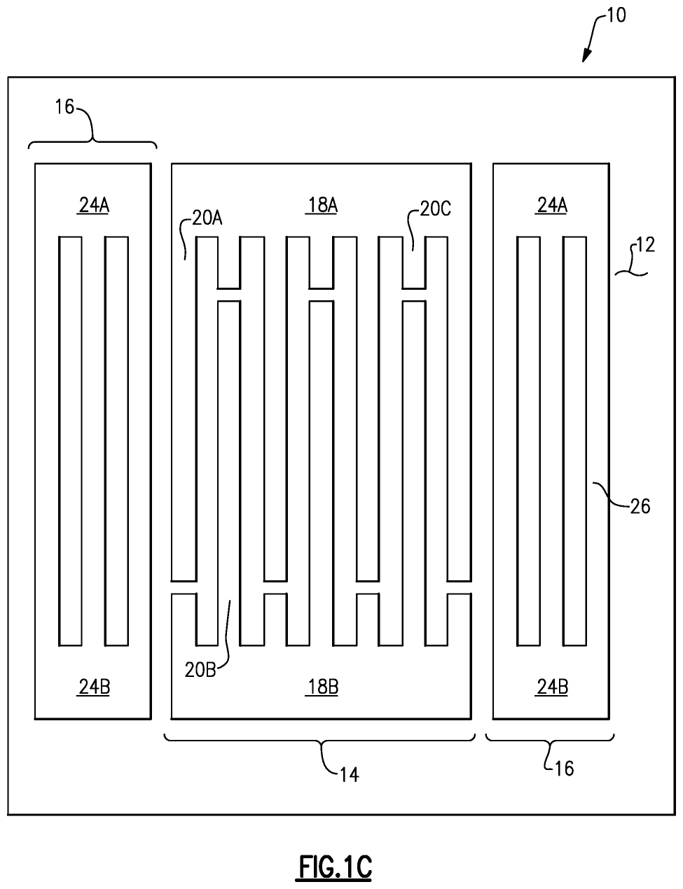

FIG. 1A is a plan view of a surface acoustic wave (SAW) resonator 10 such as might be used in a SAW filter, duplexer, balun, etc.

Acoustic wave resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing first bus bar electrode 18A. The bus bar electrodes 18A, 18B may be referred to herein and labelled in the figures as busbar electrodes 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrodes 24) and reflector fingers 26 extending between and electrically coupling the first bus bar electrode 24A and the second bus bar electrode 24B.

In other embodiments disclosed herein, as illustrated in FIG. 1B, the reflector bus bar electrodes 24A, 24B may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

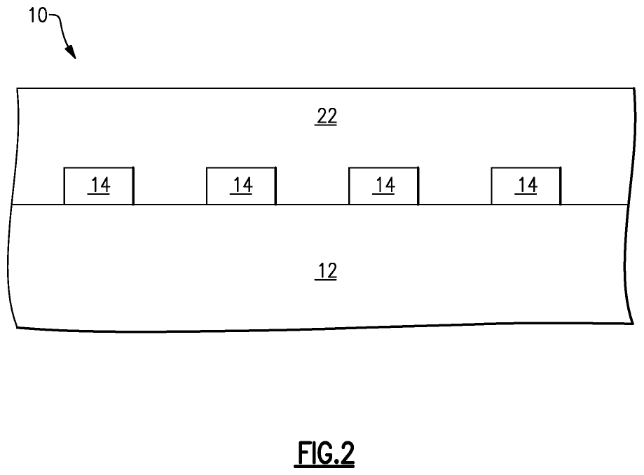

FIG. 2 is a partial cross-sectional view of a portion of the acoustic wave resonator 10 of any of FIGS. 1A-1C illustrating a few of the IDT electrodes 14 disposed on the substrate 12. The IDT electrodes 14 are formed of a metal or metal alloy, for example, aluminum. In some embodiments the IDT electrodes 14 may include multiple layers of different metals, for example, molybdenum and aluminum. In many instances, a dielectric material 22, for example, silicon dioxide (SiO₂) may be disposed on top of the IDT electrodes 14 and substrate 12. The dielectric material may advantageously decrease the effect of changes in temperature upon operating characteristics of the acoustic wave resonator 10 and may protect the IDT electrodes 14 and surface of the substrate 14. The embodiment illustrated in FIG. 2 will be referred to herein as a Baseline configuration.

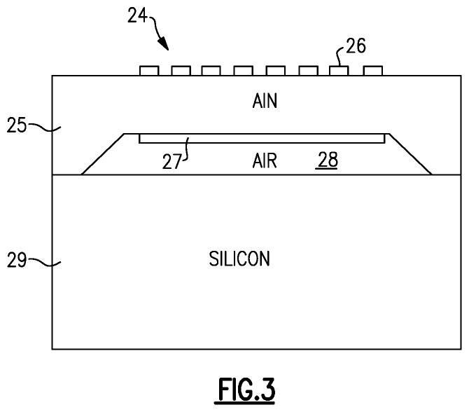

It should also be appreciated that although aspects and embodiments disclosed herein are discussed in the context of a SAW resonator, the present disclosure is equally applicable to other forms of acoustic waver resonators, for example, Lamb mode acoustic wave resonators, also referred to herein as a Lamb mode resonator or Lamb mode device. A Lamb mode acoustic wave resonator typically includes interdigital transducer (IDT) electrodes similar to a SAW resonator. For example, Lamb wave resonators also generally include an IDT electrode structure formed on a piezoelectric substrate and can benefit from a high thermal conductivity layer formed atop the IDT electrodes as disclosed herein. Examples of Lamb mode resonators that aspects and embodiments disclosed herein may be utilized in conjunction with are disclosed in commonly assigned U.S. patent application Ser. No. 16/515,302, filed on Jul. 18, 2019. One example of a Lamb mode acoustic wave resonator is shown in cross-section in FIG. 3. The Lamb mode acoustic wave resonator of FIG. 3 is illustrated without any dielectric film covering the IDT electrodes, but it should be appreciated that the configurations of dielectric films covering the substrates and/or IDT electrodes of SAW resonators as disclosed herein are equally applicable to a Lamb mode acoustic wave resonator. The Lamb wave resonator 24 includes features of a SAW resonator and a film bulk acoustic resonator. As illustrated, the Lamb wave resonator 24 includes a piezoelectric layer 25, interdigital transducer electrodes (IDT) 26 on the piezoelectric layer 25, and a lower electrode 27 disposed on a lower surface of the piezoelectric layer 25. The piezoelectric layer 25 can be a thin film. The piezoelectric layer 25 can be an aluminum nitride layer. In other instances, the piezoelectric layer 25 can be any suitable piezoelectric layer. The frequency of the Lamb wave resonator can be based on the geometry of the IDT 26. The electrode 27 can be grounded in certain instances. In some other instances, the electrode 27 can be floating. An air cavity 28 is disposed between the electrode 27 and a semiconductor substrate 29. Any suitable cavity can be implemented in place of the air cavity 28, for example, a vacuum cavity or a cavity filled with a different gas.

It should be appreciated that the acoustic wave resonators illustrated in FIGS. 1A-3, as well as those illustrated in other figures presented herein, are illustrated in a highly simplified form. The relative dimensions of the different features are not shown to scale. Further, typical acoustic wave resonators would commonly include a far greater number of electrode fingers and/or reflector fingers than illustrated. The acoustic wave resonators may be configured differently than illustrated in some examples, for example, to include dummy electrode fingers, electrode fingers with different or non-uniform length or width dimensions, electrode fingers or reflector fingers with different or non-uniform spacing, or electrode fingers that include bent or tilted portions. Typical acoustic wave resonators or filter elements may also include multiple IDT electrodes sandwiched between the reflector electrodes.

As discussed above, prior acoustic wave resonators have been formed with IDT electrodes formed of materials such as aluminum or a metal stack including a layer of aluminum and another metal, for example, molybdenum. These electrode materials proved adequate but may not be optimal. Improvements to the performance and/or form factor of an acoustic wave resonator, for example, a SAW resonator or a Lamb wave resonator may be improved upon by utilization of materials for the IDT electrodes that exhibit a greater hardness and/or density than traditional materials, for example, aluminum or an aluminum/molybdenum stack. Electrodes formed of material having increased hardness may contribute to increased quality factor of an acoustic wave resonator due to the resistance of the electrodes to deformation and the associated dissipation of energy as acoustic waves pass through the electrodes. Electrodes formed of more dense materials may transmit acoustic waves more slowly than electrodes formed of lighter materials and thus electrodes formed of more dense materials may be spaced closer together than electrodes formed of lighter materials to achieve a comparable acoustic wave frequency, providing for a reduction in size of an acoustic wave resonator including electrodes formed of the more dense material. Resistivity of the electrode material is also a consideration. If the material of the electrodes is not a good conductor of electricity, the electrodes may heat up to undesired temperatures during operation, for example, temperatures at which the operating parameters of the resonator change or temperatures that may damage the resonator or adjacent electrical components.

The following table presents data for hardness, resistivity, and density for a select number of metals that might be utilized in IDT electrodes of acoustic wave devices, as well as a figure of merit (FOM) which is a somewhat arbitrary combination of the material properties ((hardness/resistance)*density), but that provides a single number that one can use to compare the combination of properties of the different metals.

TABLE 1
Comparison of material properties of select metals

| | | Resistivity | Density | FOM |
|---|---|---|---|---|
| Metal | Mohs Hardness | (×10⁻⁶ ohm-cm) | (g/cm³) | (H/R) × D |
| Tungsten | 7.5 | 5.5 | 19.30 | 26.32 |
| Chromium | 8.5 | 2.6 | 7.15 | 23.38 |
| Copper | 3.0 | 1.7 | 8.96 | 15.81 |
| Molybdenum | 5.5 | 4.8 | 10.20 | 11.69 |
| Platinum | 3.5 | 10.5 | 21.50 | 7.17 |
| Nickel | 4.0 | 6.9 | 8.90 | 5.16 |
| Aluminum | 2.8 | 2.6 | 2.70 | 2.91 |
| Titanium | 6.0 | 47.8 | 4.51 | 0.57 |

Ac can be seen from the table above, even though metals such as tungsten and chromium have higher resistivities than aluminum, the higher hardness and density of these metals may provide resonators with electrodes formed of these metals with desirable operating properties. The density of tungsten is very high, but the resistivity of tungsten is somewhat higher than may be desirable. Chromium, having the second highest figure of merit in the table above, has a resistivity that is less than half that of tungsten. Accordingly, it may be desirable to combine these two metals to form a material for IDT electrodes of acoustic wave resonators.

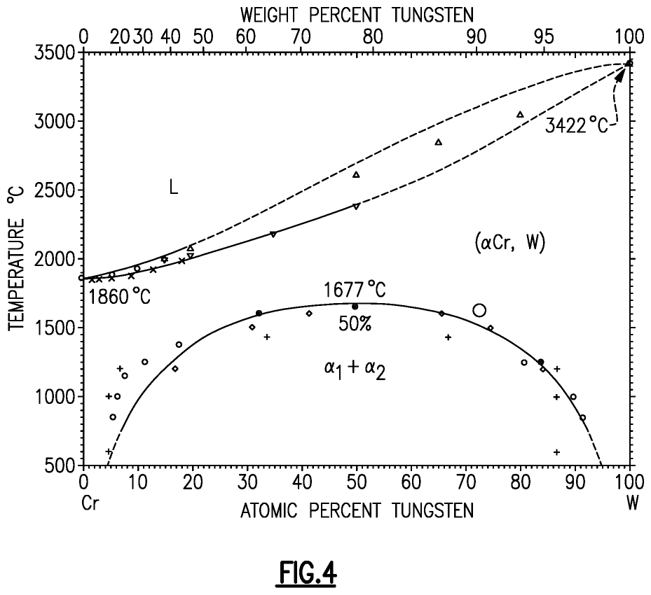

The phase diagram of the tungsten-chromium system is illustrated in FIG. 4. As shown in this phase diagram, alloys of tungsten and chromium may form complete solid solutions at high temperatures. At lower temperatures, for example, within the expected operating temperature range of an acoustic wave resonator, mixtures of tungsten and chromium form a dual phase system of α₁ and α₂ alloys at chromium (or tungsten) concentrations of from 5 at % to 95 at %. Experimental data has shown that sintered bodies of 80 at % tungsten to 20 at % chromium or 90 at % tungsten to 10 at % chromium may exhibit Vickers Microhardnesses of between 400 and 1500, depending on sintering time and temperature.

In accordance with various embodiments, acoustic wave resonators, for example SAW resonators or Lamb wave devices may include IDT electrodes and/or reflector electrodes formed of a mixture of tungsten and chromium. The mixture may be a dual phase system of different alloys of tungsten and chromium, for example, two different alloys of tungsten and chromium. The mixture may include from 5% to 95% chromium and from 5% to 95% tungsten. Powders and sputtering targets of 90% tungsten/10% chromium are commercially available from suppliers such as Goodfellow Alloys and American Elements.

Metal films, for example, metal films including a mixture of tungsten and chromium may be deposited on a substrate, for example, a piezoelectric substrate to form IDT electrodes and/or reflector electrodes using any method for depositing metal films known in the art. Such methods may include physical vapor deposition, for example, sputtering or evaporation deposition, stencil printing of a paste including the metal mixture followed by curing, electroplating, or chemical vapor deposition. Patterning of the metal film to form the IDT electrodes and/or reflector electrodes may be performed by a lift-off method or by etching.

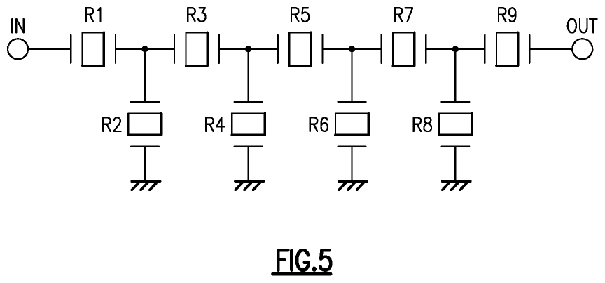

In some embodiments, multiple acoustic wave resonators as disclosed herein may be combined into a filter, for example, an RF ladder filter schematically illustrated in FIG. 5 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

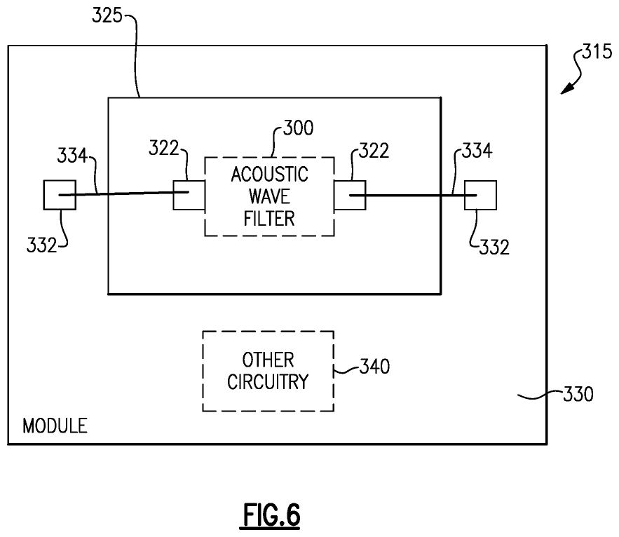

Examples of the acoustic wave devices, e.g., SAW resonators or Lamb wave resonators discussed herein can be implemented in a variety of packaged modules. Some example packaged modules will now be discussed in which any suitable principles and advantages of the acoustic wave devices discussed herein can be implemented. FIGS. 6, 7, and 8 are schematic block diagrams of illustrative packaged modules and devices according to certain embodiments.

As discussed above, acoustic wave resonators can be used in acoustic wave RF filters. In turn, an RF filter using one or more acoustic wave elements may be incorporated into and packaged as a module that may ultimately be used in an electronic device, such as a wireless communications device, for example. FIG. 6 is a block diagram illustrating one example of a module 315 including an acoustic wave filter 300. The acoustic wave filter 300 may be implemented on one or more die(s) 325 including one or more connection pads 322. For example, the acoustic wave filter 300 may include a connection pad 322 that corresponds to an input contact for the acoustic wave filter and another connection pad 322 that corresponds to an output contact for the acoustic wave filter. The packaged module 315 includes a packaging substrate 330 that is configured to receive a plurality of components, including the die 325. A plurality of connection pads 332 can be disposed on the packaging substrate 330, and the various connection pads 322 of the acoustic wave filter die 325 can be connected to the connection pads 332 on the packaging substrate 330 via electrical connectors 334, which can be solder bumps or wirebonds, for example, to allow for passing of various signals to and from the acoustic wave filter 300. The module 315 may optionally further include other circuitry die 340, for example, one or more additional filter(s), amplifiers, pre-filters, modulators, demodulators, down converters, and the like, as would be known to one of skill in the art of semiconductor fabrication in view of the disclosure herein. In some embodiments, the module 315 can also include one or more packaging structures to, for example, provide protection and facilitate easier handling of the module 315. Such a packaging structure can include an overmold formed over the packaging substrate 330 and dimensioned to substantially encapsulate the various circuits and components thereon.

Various examples and embodiments of the acoustic wave filter 300 can be used in a wide variety of electronic devices. For example, the acoustic wave filter 300 can be used in an antenna duplexer, which itself can be incorporated into a variety of electronic devices, such as RF front-end modules and communication devices.

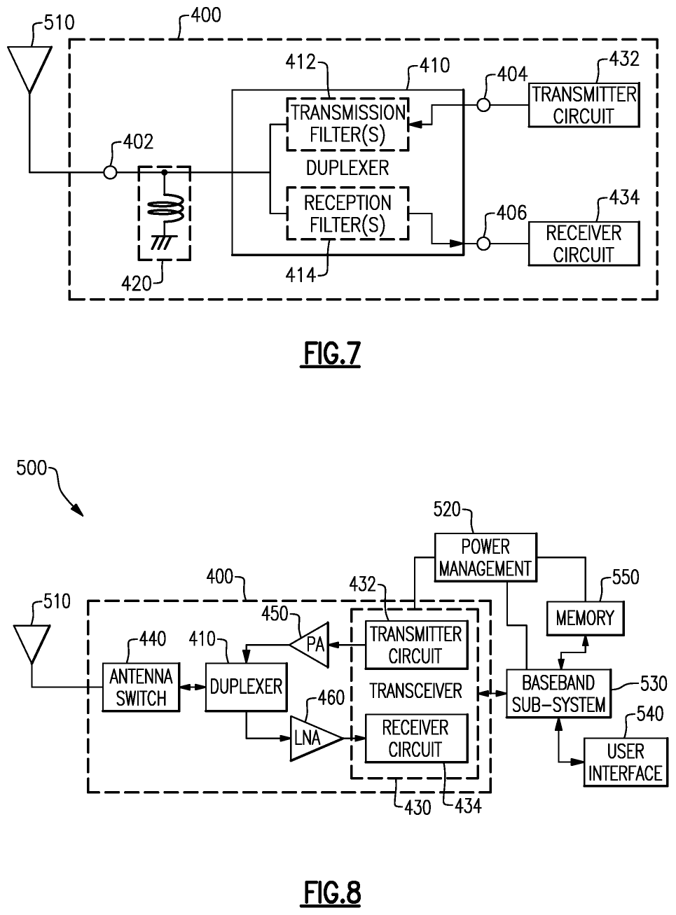

Referring to FIG. 7, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the acoustic wave filter 300 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 7, however, in other embodiments these components may be integrated into a common transceiver circuit or module. As will be appreciated by those skilled in the art, the front-end module 400 may include other components that are not illustrated in FIG. 7 including, but not limited to, switches, electromagnetic couplers, amplifiers, processors, and the like.

FIG. 8 is a block diagram of one example of a wireless device 500 including the antenna duplexer 410 shown in FIG. 7. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 7. The front-end module 400 includes the duplexer 410, as discussed above. In the example shown in FIG. 8 the front-end module 400 further includes an antenna switch 440, which can be configured to switch between different frequency bands or modes, such as transmit and receive modes, for example. In the example illustrated in FIG. 8, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 8.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 8, the front-end module 400 may further include a low noise amplifier module 460, which amplifies received signals from the antenna 510 and provides the amplified signals to the receiver circuit 434 of the transceiver 430.

The wireless device 500 of FIG. 8 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A acoustic wave resonator comprising:
a piezoelectric substrate; and
a plurality of interdigital transducer (IDT) electrodes disposed on the piezoelectric substrate, the plurality of IDT electrodes formed of a mixture of tungsten and chromium to provide for reduction in size and increase in quality factor of the acoustic wave resonator.

2. The resonator of claim 1 further comprising reflector electrodes formed of the mixture of tungsten and chromium.

3. The resonator of claim 1 wherein the mixture is a two-phase mixture of two different alloys of tungsten and chromium.

4. The resonator of claim 3 wherein mixture includes between 5 at % and 95 at % tungsten and from 5 at % to 95 at % chromium.

5. The resonator of claim 3 wherein the mixture includes about 90 at % tungsten and about 10 at % chromium.

6. The resonator of claim 1 configured as a surface acoustic wave resonator.

7. The resonator of claim 1 configured as a Lamb wave resonator.

8. A radio frequency filter including the acoustic wave resonator of claim 1.

9. An electronics module including the radio frequency filter of claim 8.

10. An electronic device including the electronics module of claim 9.
